(19) United States
(12) Patent Application Publication
(10) Pub. No.: US 2024/0334651 A1
(43) Pub. Date: Oct. 3, 2024

(54) Fluid Assisted Thermoelectric PCB Thermal Management System

(71) Applicant: Panasonic Automotive Systems Company of America, Division of Panasonic Corporation of North America, Peachtree City, GA (US)

(72) Inventor: NICHOLAS BRIAN HANSEN, FAYETTEVILLE, GA (US)

(21) Appl. No.: 18/623,167

(22) Filed: Apr. 1, 2024

Related U.S. Application Data
(60) Provisional application No. 63/456,065, filed on Mar. 31, 2023.

(51) Int. Cl. H05K 7/20; H05K 1/02; H10N 19/00

(52) U.S. Cl. CPC H05K 7/20327; H05K 1/0203; H10N 19/00; H05K 7/20881; H05K 2201/064; H05K 2201/10219

(57) ABSTRACT

A cooling system for electronics includes an electronic component to be cooled, a first chamber containing the electronic component, means for converting heat into electrical energy, a second chamber containing the converting means, a first conduit fluidly interconnecting the first chamber and the second chamber, a second conduit fluidly interconnecting the first chamber and the second chamber such that the first chamber, the second chamber, the first conduit and the second conduit form a fluid circuit. Thermal transfer fluid is disposed in the fluid circuit, wherein the fluid circuit circulates the thermal transfer fluid therein.

### CROSS-REFERENCED TO RELATED APPLICATIONS

This application claims benefit of U.S. Provisional Application No. 63/456,065, filed on Mar. 31, 2023, the disclosure of which is hereby incorporated by reference in its entirety for all purposes.

### BACKGROUND OF THE INVENTION

### 1. Field of the Invention

The present invention relates to cooling systems for automotive electronics.

### 2. Description of the Related Art

Most electronic devices that require cooling are cooled using a heat sink and some sort of convection, either natural or forced, to remove the thermal energy from the heat sink. However, some integrated circuits on a printed circuit board (PCB) cannot be cooled via a traditional method such as with a fan and heat sink. This is because many devices, such as switches in vehicles, are mounted in areas without substantial air flow.

Cooling can be accomplished via convection or liquid cooling and convection if the location of the device allows for it. Liquid cooling using pumps and radiators is possible. The liquid must be transported from the high temperature area to an area where convection can then be used to reduce the temperature of the fluid at the radiator.

### SUMMARY OF THE INVENTION

The invention may provide a method for cooling an integrated circuit on a PCB that cannot be cooled via a more traditional method such as a fan and heat sink. By converting the thermal energy into electrical energy, the invention may enable transfer of the energy via electrical conduction rather than convection. The invention may exploit the latent heat of evaporation of thermal transfer fluid and the associated increase in pressure along with the thermoelectric effect to make removal of the thermal energy via electrical conduction possible.

The invention comprises, in one form thereof, a cooling system for electronics, including an electronic component to be cooled, a first chamber containing or adjacent to the electronic component, means for converting heat into electrical energy, a second chamber containing the converting means, a first conduit fluidly interconnecting the first chamber and the second chamber, a second conduit fluidly interconnecting the first chamber and the second chamber such that the first chamber, the second chamber, the first conduit and the second conduit form a fluid circuit. Thermal transfer fluid is disposed in the fluid circuit, wherein the fluid circuit circulates the thermal transfer fluid therein.

The invention comprises, in another form thereof, a method for cooling an electronic component. The method includes providing a sealed fluid circuit having a first chamber, a second chamber, a first fluid conduit interconnecting the first chamber and the second chamber, and a second fluid conduit interconnecting the first chamber and the second chamber. The electronic component is placed in the first chamber. Thermal transfer fluid is placed in the fluid circuit such that heat from the electronic component is transferred to the thermal transfer fluid. The thermal transfer fluid is circulated within the sealed fluid circuit. Heat from the thermal transfer fluid is converted into electrical energy. The converting occurs within the second chamber.

The invention comprises, in yet another form thereof, a cooling system for cooling an electronic component. The system includes a first chamber containing the electronic component. At least one Seebeck effect thermoelectric junction converts heat into electrical energy. A second chamber contains the at least one Seebeck effect thermoelectric junction. A first conduit fluidly interconnects the first chamber and the second chamber. A second conduit fluidly interconnects the first chamber and the second chamber such that the first chamber, the second chamber, the first conduit and the second conduit form a fluid circuit. Thermal transfer fluid is disposed in the fluid circuit. The fluid circuit circulates the thermal transfer fluid therein.

### BRIEF DESCRIPTION OF THE DRAWINGS

The above-mentioned and other features and objects of this invention, and the manner of attaining them, will become more apparent and the invention itself will be better understood by reference to the following description of embodiments of the invention taken in conjunction with the accompanying drawings, wherein:

FIG. 1 is a schematic diagram of one embodiment of a fluid assisted thermoelectric PCB thermal management system of the present invention.

FIG. 2 is a flow chart of one embodiment of a method of the invention for cooling an electronic component.

### DETAILED DESCRIPTION

The embodiments hereinafter disclosed are not intended to be exhaustive or limit the invention to the precise forms disclosed in the following description. Rather the embodiments are chosen and described so that others skilled in the art may utilize its teachings.

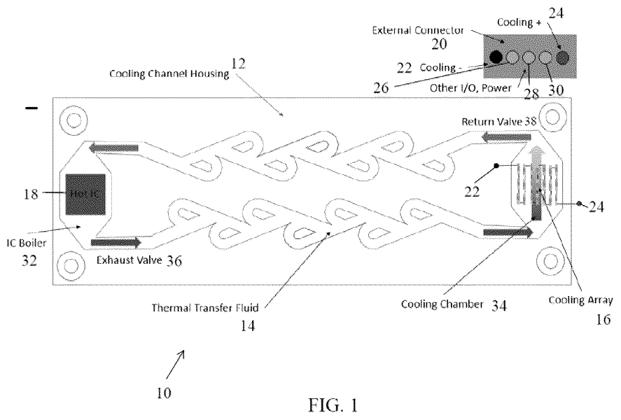

FIG. 1 illustrates one embodiment of a fluid assisted thermoelectric PCB thermal management system 10 of the present invention, including a channel guide housing 12 filled with an alcohol-based thermal transfer fluid 14, a cooling array 16, a PCB (not shown) that includes a hot integrated circuit (IC) 18 that needs cooling and an external connector 20 having one or more electrical connections to an external environment. Alternatively, the IC and/or the cooling array could be on the reverse side of the PCB. The electrical connections include a negative cooling connection 22, a positive cooling connection 24, and other connections 26, 28 and 30 for input/output (I/O) and power.

Channel guide housing 12 may be sealed such that thermal transfer fluid 14 cannot leak out. Channel guide housing 12 connects an IC boiler 32, which is situated adjacent to the integrated circuit 18 that requires cooling, to a cooling chamber 34 which contains cooling array 16. IC boiler 32 and cooling chamber 34 are connected via a pair of Tesla valves to form a complete fluid circuit through which thermal transfer fluid 14 circulates. One Tesla valve, the exhaust valve 36, is situated such that fluid heated in IC boiler 32 can flow to cooling chamber 34. The other Tesla valve, the return valve 38, is situated such that fluid can return from cooling chamber 34 to IC boiler 32. The pair of valves 36, 38 promotes and produces a single direction of fluid travel.

Cooling array 16 may include several Seebeck effect thermoelectric junctions arranged in a substantially series configuration from an electrical perspective and substantially parallel configuration from a thermal perspective. Cooling array 16 may convert thermal energy contained within thermal transfer fluid 14 into electrical energy that can then be transferred via external wiring away from the PCB supporting fluid assisted thermoelectric PCB thermal management system 10. Each Seebeck effect thermoelectric junction may include two wires each made of a different respective metal. An end of each wire may be joined together within cooling chamber 34. The other ends of the wires (e.g., negative cooling connection 22 and positive cooling connection 24) may be disposed outside of cooling chamber 34 where the temperature is lower. As is well known, this results in a voltage difference between negative cooling connection 22 and positive cooling connection 24. The voltage may be applied to a load to create a current flow and power dissipation that is “fueled” by the elevated temperature within cooling chamber 34, resulting in a reduction of the temperature within chamber 34.

Thermal transfer fluid 14 may have a boiling point below the maximum allowable operating temperature of IC 18 that requires cooling. IC boiler 32 may enable thermal energy emitted from IC 18 to raise the temperature of fluid 14 to the boiling point such that some of fluid 14 is in the gaseous state and IC boiler 32 experiences an increase in pressure. The increased pressure may cause fluid 14 to flow out of IC boiler 32 via exhaust valve 36 and into cooling chamber 34. Cooling array 16 may then convert some of the thermal energy into electrical energy and reduce the temperature of fluid 14. The reduced temperature fluid 14 then exits the cooling chamber 34 via return valve 38 to reduce the temperature of IC boiler 32. The cycle then repeats to hold the temperature of IC 18 near the boiling point of thermal transfer fluid 14.

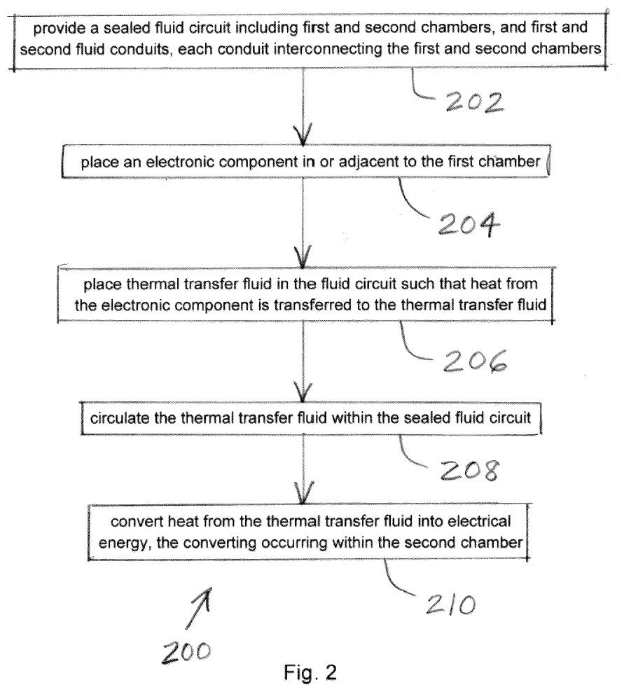

FIG. 2 is a flow chart of one embodiment of a method 200 of the invention for cooling an electronic component. In a first step 202, a sealed fluid circuit is provided, including a first chamber, a second chamber, a first fluid conduit interconnecting the first chamber and the second chamber, and a second fluid conduit interconnecting the first chamber and the second chamber. For example, IC boiler 32 and cooling chamber 34 are connected via exhaust valve 36 and return valve 38.

Next, in step 204, the electronic component is placed in or adjacent to the first chamber. For example, integrated circuit 18 may be placed in IC boiler 32.

In a next step 206, thermal transfer fluid is placed in the fluid circuit such that heat from the electronic component is transferred to the thermal transfer fluid. For example, alcohol-based thermal transfer fluid 14 may be placed in IC boiler 32 and cooling chamber 34 such that heat from integrated circuit 18 is transferred to fluid 14.

In step 208, the thermal transfer fluid is circulated within the sealed fluid circuit. For example, thermal transfer fluid 14 may be circulated between IC boiler 32 and cooling chamber 34 due to the higher pressure in IC boiler 32, and due to the Tesla valves interconnecting IC boiler 32 and cooling chamber 34.

In a final step 210, heat from the thermal transfer fluid is converted into electrical energy. The converting occurs within the second chamber. For example, cooling array 16 within cooling chamber 34 may convert thermal energy contained within thermal transfer fluid 14 into electrical energy.

While this invention has been described as having an exemplary design, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

What is claimed is:

1. A cooling system for electronics, the system comprising:
an electronic component to be cooled;
a first chamber containing or adjacent to the electronic component;
means for converting heat into electrical energy;
a second chamber containing or adjacent to the converting means;
a first conduit fluidly interconnecting the first chamber and the second chamber;
a second conduit fluidly interconnecting the first chamber and the second chamber such that the first chamber, the second chamber, the first conduit and the second conduit form a fluid circuit; and
thermal transfer fluid disposed in the fluid circuit, wherein the fluid circuit is configured to circulate the thermal transfer fluid therein.

2. The system of claim 1 wherein the converting means comprises at least one thermoelectric junction.

3. The system of claim 2 wherein the at least one thermoelectric junction comprises a plurality of thermoelectric junctions.

4. The system of claim 3 wherein the plurality of thermoelectric junctions are connected together electrically in series and thermally substantially in parallel.

5. The system of claim 1 wherein the first conduit comprises a first Tesla valve.

6. The system of claim 5 wherein the second conduit comprises a second Tesla valve.

7. The system of claim 1 wherein the first conduit comprises a first one-way valve, and the second conduit comprises a second one-way valve.

8. A method for cooling an electronic component, the method comprising:
providing a sealed fluid circuit including:
a first chamber;
a second chamber;
a first fluid conduit interconnecting the first chamber and the second chamber; and
a second fluid conduit interconnecting the first chamber and the second chamber;
placing the electronic component in or adjacent to the first chamber;
placing thermal transfer fluid in the fluid circuit such that heat from the electronic component is transferred to the thermal transfer fluid;
circulating the thermal transfer fluid within the sealed fluid circuit; and
converting heat from the thermal transfer fluid into electrical energy, the converting occurring within the second chamber.

9. The method of claim 8 wherein the converting step is performed by using at least one thermoelectric junction.

10. The method of claim 9 wherein the at least one thermoelectric junction comprises a plurality of thermoelectric junctions.

11. The method of claim 10 further comprising connecting the plurality of thermoelectric junctions together electrically in series and thermally substantially in parallel.

12. The method of claim 8 wherein the first fluid conduit comprises a first Tesla valve.

13. The method of claim 12 wherein the second conduit comprises a second Tesla valve.

14. The method of claim 8 wherein the first fluid conduit comprises a first one-way valve, and the second fluid conduit comprises a second one-way valve.

15. A cooling system for cooling an electronic component, the system comprising:
a first chamber configured to contain or adjacent to the electronic component;
at least one Seebeck effect thermoelectric junction configured to convert heat into electrical energy;
a second chamber containing or adjacent to the at least one Seebeck effect thermoelectric junction;
a first conduit fluidly interconnecting the first chamber and the second chamber;
a second conduit fluidly interconnecting the first chamber and the second chamber such that the first chamber, the second chamber, the first conduit and the second conduit form a fluid circuit; and
thermal transfer fluid disposed in the fluid circuit, wherein the fluid circuit is configured to circulate the thermal transfer fluid therein.

16. The system of claim 15 wherein the at least one Seebeck effect thermoelectric junction comprises a plurality of Seebeck effect thermoelectric junctions.

17. The system of claim 16 wherein the plurality of Seebeck effect thermoelectric junctions are connected together electrically in series and thermally substantially in parallel.

18. The system of claim 15 wherein the first conduit comprises a first Tesla valve.

19. The system of claim 18 wherein the second conduit comprises a second Tesla valve.

20. The system of claim 15 wherein the first conduit comprises a first one-way valve, and the second conduit comprises a second one-way valve.
